(19) United States
(12) Patent Application Publication
(10) Pub. No.: US 2025/0301603 A1
(43) Pub. Date: Sep. 25, 2025

(54) PRE-COOLING DEVICE INTEGRATED LIQUID COOLING DISTRIBUTOR AND ITS SERVER LIQUID COOLING SYSTEM

(71) Applicant: Super Micro Computer, Inc., San Jose, CA (US)

(72) Inventors: Chia-Wei CHEN, New Taipei City (TW); Kun-Chieh LIAO, New Taipei City (TW); Yueh-Ming LIU, New Taipei City (TW)

(21) Appl. No.: 19/233,506

(22) Filed: Jun. 10, 2025

Related U.S. Application Data
(63) Continuation of application No. 18/176,120, filed on Feb. 28, 2023, now Pat. No. 12,356,589.

(30) Foreign Application Priority Data
Oct. 28, 2022 (TW) 111211834

(51) Int. Cl. H05K 7/20

(52) U.S. Cl. CPC H05K 7/20327; H05K 7/20318; H05K 7/20818

(57) ABSTRACT

A precooling device integrated with a cooling distribution unit and a server liquid cooling system are provided. The precooling device includes a liquid cooling row, an adapter assembly, and a cooling distribution unit. The adapter assembly includes a flow joining row and a flow distribution row. The cooling distribution unit supplies a refrigerant from an interior thereof, and includes an outlet and an inlet communicating with the interior. The outlet communicates with the flow distribution row of the adapter assembly to deliver the refrigerant for heat exchange. The refrigerant being performed the heat exchange returns to the liquid cooling row through the flow joining row of the adapter assembly for precooling, and then returns from the liquid cooling row to the cooling distribution unit through the inlet. The refrigerant is precooled before returning to the cooling distribution unit.

### CROSS-REFERENCE TO RELATED APPLICATIONS

This application is a continuation of U.S. application Ser. No. 18/176,120, filed on Feb. 28, 2023, and claims the benefit of Taiwanese Patent Application No. 111211834, filed on Oct. 28, 2022. The entire contents of each of the related applications noted above are hereby incorporated by reference.

### BACKGROUND OF THE DISCLOSURE

### Technical Field

The present disclosure is related to a cooling device, especially a precooling device integrated with a cooling distribution unit and a server liquid cooling system having the same.

### Description of Related Art

The related-art cooling distribution units (CDU) are refrigerant-type heat dissipation devices used for cloud devices such as servers. The CDU mainly distributes a refrigerant, supplied from the outside or stored inside, through multiple pipelines, so as to effectively control required condensation or desired cooling temperatures, thereby achieving cooling and heat dissipation for a system.

During use of the related-art CDU, a temperature of the refrigerant rises after the refrigerant delivered by the CDU undergoes heat exchange with other external electronic components or heating elements. Therefore, when the higher-temperature refrigerant flows back into the CDU, the refrigerant often needs to be cooled by the CDU, so that the CDU can maintain the refrigerant supplied by itself at required low temperatures.

In light of the above, the inventor of the present disclosure has devoted himself to doing research and studying scientific principles and therefore can provide the present disclosure to solve the above problem of conventional techniques.

### SUMMARY OF THE DISCLOSURE

It is a main objective of the present disclosure to provide a precooling device integrated with a cooling distribution unit and a server liquid cooling system. The present disclosure may reduce the influence of temperature rise on a refrigerant inside the cooling distribution unit by precooling the refrigerant before the refrigerant being delivered by the cooling distribution unit returns, so that it is easier to maintain the refrigerant inside the cooling distribution unit at sufficiently or expectedly low temperatures.

To achieve the above-mentioned objective, the present disclosure provides a precooling device integrated with a cooling distribution unit, including a liquid cooling row, an adapter assembly, and a cooling distribution unit. The liquid cooling row includes a condensation area, a flow distribution side communicating with one side of the condensation area, and a flow joining side communicating with another side of the condensation area. The adapter assembly includes a flow joining row and a flow distribution row. The flow joining row communicates with the flow distribution side of the liquid cooling row. The cooling distribution unit supplies a refrigerant from an interior of the cooling distribution unit, and includes an outlet and an inlet communicating with the interior of the cooling distribution unit. The outlet communicates with the flow distribution row of the adapter assembly to deliver the refrigerant for heat exchange. The refrigerant being performed the heat exchange returns through the flow joining row of the adapter assembly to the condensation area of the liquid cooling row for precooling, and then returns from the flow joining side of the liquid cooling row to the cooling distribution unit through the inlet.

To achieve the above-mentioned objective, the present disclosure provides a server liquid cooling system with a precooling device integrated with a cooling distribution unit, including: a server cabinet, at least one server chassis mounted on the server cabinet, and the cooling distribution unit arranged in the server cabinet. A refrigerant is supplied from an interior of the cooling distribution unit, and the cooling distribution unit includes an outlet and an inlet communicating with the interior of the cooling distribution unit. A liquid cooling row and an adapter assembly are disposed between the cooling distribution unit and the server chassis. The liquid cooling row includes a condensation area, a flow distribution side communicating with one side of the condensation area, and a flow joining side communicating with another side of the condensation area. The adapter assembly includes a flow joining row and a flow distribution row, and the flow joining row communicates with the liquid distribution side of the liquid cooling row. The outlet of the cooling distribution unit communicates with the flow distribution row of the adapter assembly to deliver the refrigerant into the server chassis for heat exchange. The refrigerant being performed the heat exchange returns through the flow joining row of the adapter assembly to the condensation area of the liquid cooling row for precooling, and then returns from the flow joining side of the liquid cooling row to the cooling distribution unit through the inlet of the cooling distribution unit.

### BRIEF DESCRIPTION OF THE DRAWINGS

FIG. 1 is a perspective exploded view of a precooling device of the present disclosure.

FIG. 2 is a perspective exploded view illustrating the present disclosure used in a server chassis.

FIG. 3 is a perspective assembled view illustrating the present disclosure used in the server chassis.

FIG. 4 is a schematic top view illustrating the present disclosure used in the server chassis.

FIG. 5 is a schematic perspective view illustrating the present disclosure used in a server cabinet.

### DETAILED DESCRIPTION

A detailed description and technical content of the present disclosure are provided below with reference to accompanying drawings. However, the accompanying drawings are only for illustrative purposes and are not intended to limit the present disclosure.

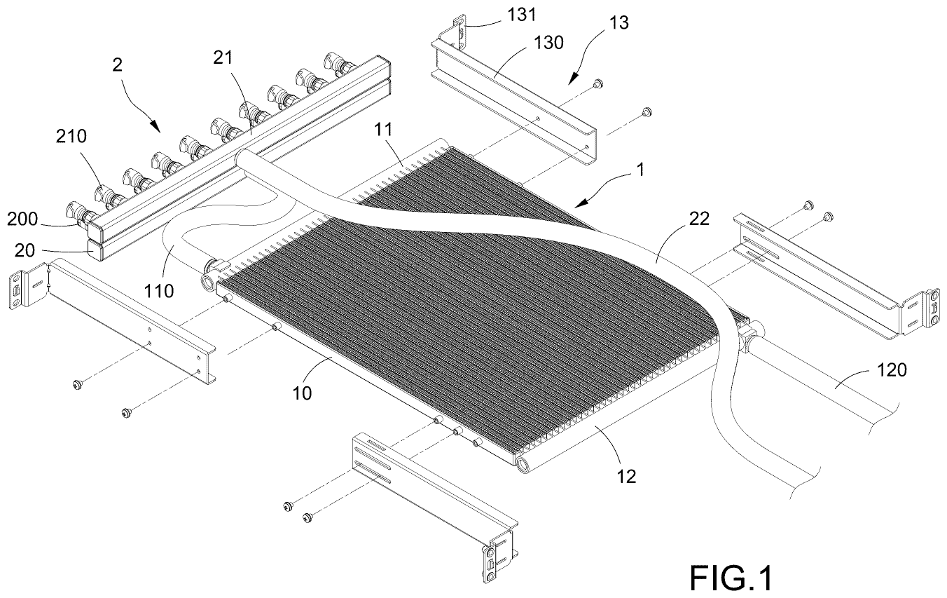

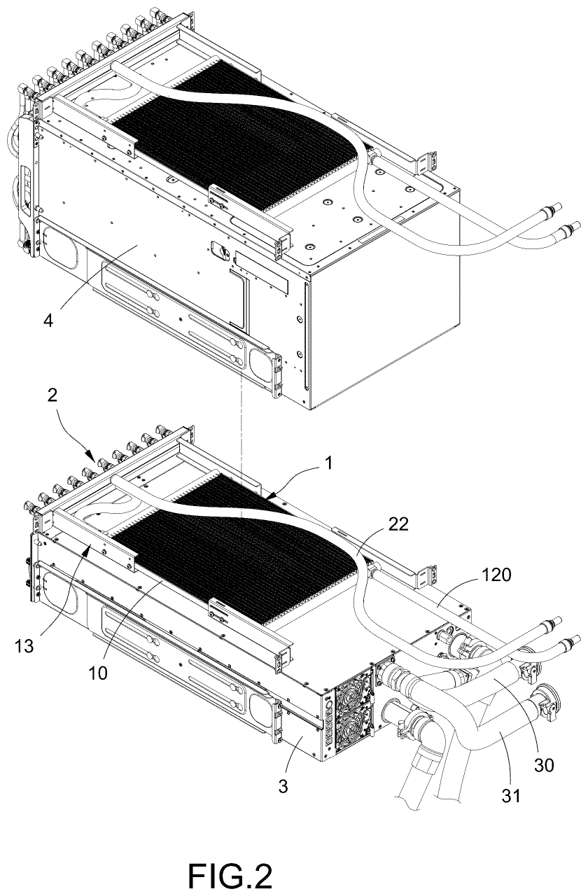

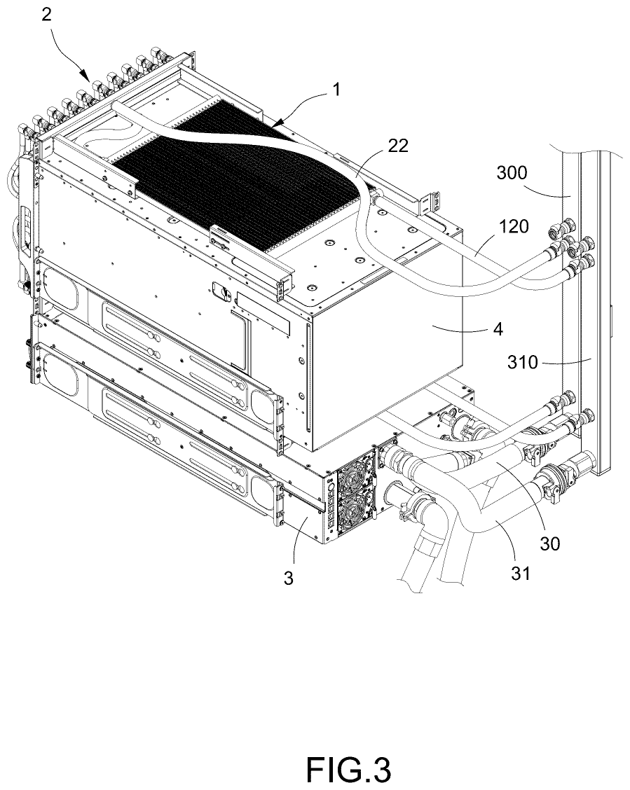

Please refer to FIG. 1, FIG. 2, and FIG. 3, which are a perspective exploded view of a precooling device of the present disclosure, and a perspective exploded view and a perspective assembled view of the present disclosure used in a server chassis. The present disclosure provides a precooling device integrated with a cooling distribution unit and provides a server liquid cooling system. The precooling device includes a liquid cooling row 1, an adapter assembly 2, and a cooling distribution unit 3, and the precooling device may be cooperated with at least one server chassis 4 to dissipate heat. The server chassis 4 includes electronic components disposed inside, such as a motherboard, a central processing unit (CPU) and a storage medium, to function as a computer for independent calculation or processing.

The liquid cooling row 1 includes a condensation area 10, a flow distribution side 11 communicating with one side of the condensation area 10, and a flow joining side 12 communicating with another side of the condensation area 10. The liquid cooling row 1 is used to communicate between the above-mentioned cooling distribution unit 3 and the server chassis 4. Therefore, after precooled, the refrigerant being supplied to the server chassis 4 for cooling returns to the cooling distribution unit 3. The liquid cooling row 1 may be arranged as fins and pipes, so that precooling may be achieved by the refrigerant flowing inside the liquid cooling row 1 to make heat exchange.

The adapter assembly 2 includes a flow joining row (or flow joining passage) 20 and a flow distribution row (or flow distribution passage) 21. The adapter assembly 2 is disposed adjacent to the flow distribution side 11 of the above-mentioned liquid cooling row 1. The flow joining row 20 may be disposed under the flow distribution row 21, and disposed on substantially the same horizontal level as the above-mentioned liquid cooling row 1. The flow distribution side 11 of the liquid cooling row 1 communicates with the flow joining row 20 through a return tube 110. The flow joining row 20 is provided with a plurality of flow joining tubes 200, and the flow distribution row 21 is provided with a plurality of flow distribution tubes 210. The flow joining tubes 200 and the flow distribution tubes 210 all communicate with the above-mentioned server chassis 4. Accordingly, the refrigerant flowing through the server chassis 4 returns to the flow joining row 20 through the flow joining tubes 200, and then enters the liquid cooling row 1 through the return tube 110 to precool the refrigerant. The flow distribution row 21 communicates with the cooling distribution unit 3 through a conveying tube 22. Accordingly, the refrigerant supplied by the cooling distribution unit 3 is delivered to the server chassis 4 through the flow distribution tubes 210 of the flow distribution row 21 to take away heat from the server chassis 4.

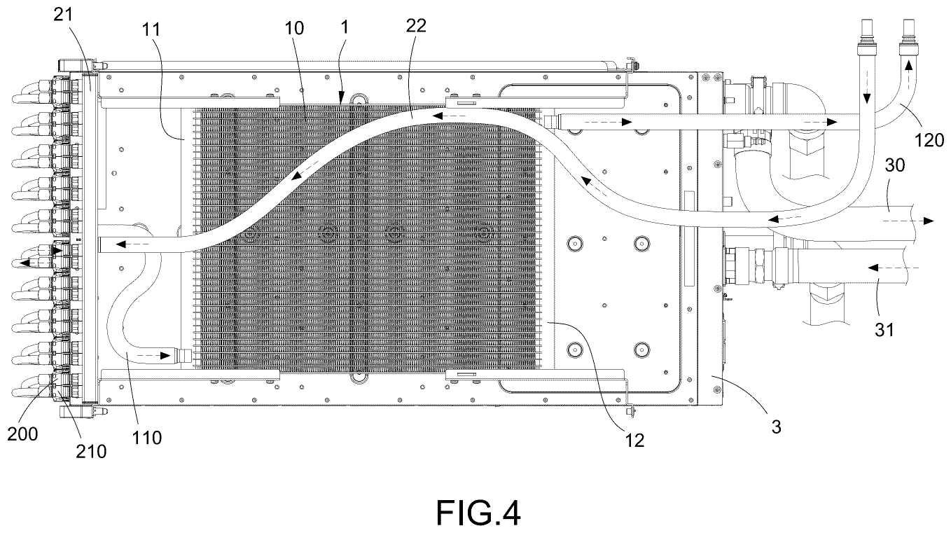

The cooling distribution unit (CDU) 3 is used to supply the required refrigerant. The refrigerant may be various working fluids for cooling, such as a cooling agent. Please also refer to FIG. 4, the cooling distribution unit 3 mainly includes an outlet 30 and an inlet 31 communicating with the interior of the cooling distribution unit 3, so that the refrigerant inside the cooling distribution unit 3 is supplied to the adapter assembly 2 of the precooling device through the outlet 30 communicating with the conveying tube 22, and then is delivered to the server chassis 4 through the flow distribution row 21 of the adapter assembly 2. After the refrigerant undergoes heat exchange in the server chassis 4, the refrigerant is sent back to the flow joining row 20 of the adapter assembly 2 to be delivered to the liquid cooling row 1 of the precooling device through the return tube 110 for precooling. The flow joining side 12 of the liquid cooling row 1 is connected to the inlet 31 with an input tube 120, so that the refrigerant may be sent back to the cooling distribution unit 3 for cooling.

In summary, in the present disclosure, before the refrigerant returns to the cooling distribution unit 3 following the heat exchange, that is, the refrigerant is outside the inlet 31 of the cooling distribution unit 3, the refrigerant may return to the liquid cooling row 1 of the precooling device to be precooled in advance. Consequently, the refrigerant is cooled to a certain extent before entering the cooling distribution unit 3, and then flows into the cooling distribution unit 3. In this way, the refrigerant stored in the cooling distribution unit 3 may be prevented from being affected by a temperature rise of the refrigerant undergoing the heat exchange, so that the refrigerant in the cooling distribution unit 3 may be kept at sufficiently low temperatures.

Please also refer to FIG. 2 and FIG. 3. The present disclosure may further dissipate heat for the above-mentioned server chassis 4. Each time one server chassis 4 is added, one precooling device is also added. In the above-mentioned embodiment, the corresponding precooling devices are stacked on the cooling distribution unit 3. In the configuration of a server, each precooling device has a thickness which is commonly called “1 U” (namely 1 rack unit, which is about 4.45 mm) thickness, so that the precooling device with the “1 U” thickness is arranged between any two server chassis 4, when the server chassis 4 are stacked. Specifically, as shown in FIG. 1, in the present disclosure, a plurality of frames 13 are arranged laterally between the liquid cooling row 1 and the adapter assembly 2. Each of the frames 13 includes a side portion 130 fixed outside the condensation area 10 and an end portion 131 fixed to the adapter assembly 2. The side portion 130 and the end portion 131 may form an “L” shape to position the adapter assembly 2 on one side adjacent to the flow distribution side 11 of the liquid cooling row 1, so that under the “1 U” thickness space configuration, the precooling device is stacked above the cooling distribution unit 3 (or disposed between the cooling distribution unit 3 and the adjacent server chassis 4), or disposed between any two adjacent server chassis 4. Accordingly, the refrigerant supplied by the cooling distribution unit 3 to any server chassis 4 is precooled before returning to the cooling distribution unit 3.

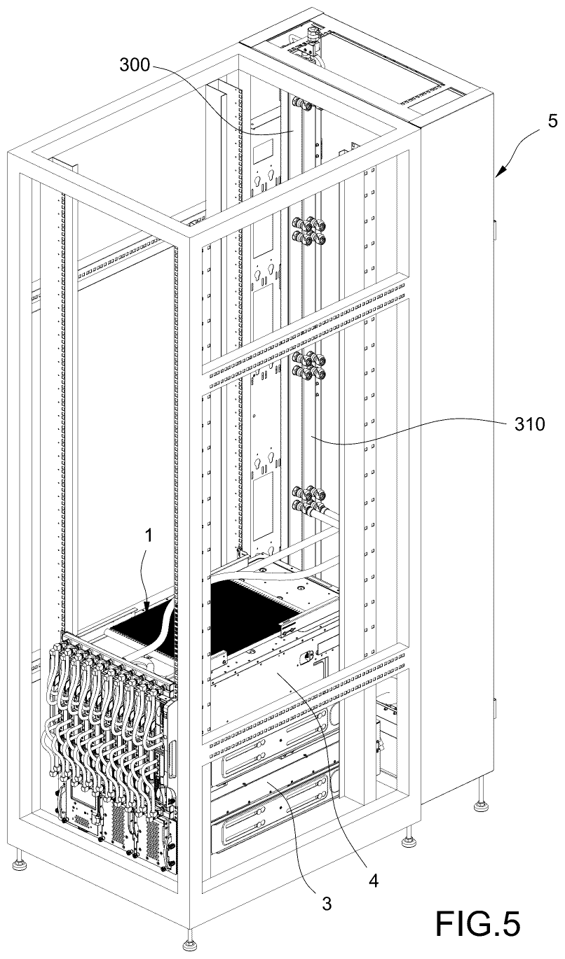

Furthermore, as shown in FIG. 5, in order to facilitate flowing of the refrigerant between the server chassis 4 after the server chassis 4 are stacked, a server cabinet 5, where each server chassis 4 is mounted, may be provided with an outgoing row (or outgoing pipe) 300 and an intake row (or intake pipe) 310 arranged vertically. The above-mentioned cooling distribution unit 3 is located under each server chassis 4. The outgoing row 300 and the intake row 310 are arranged side by side at any corner or an inner frame of the server cabinet 5. Each outgoing row 300 is used to communicate with the outlet 30 of the cooling distribution unit 3 and the conveying tube 22 of each adapter assembly 2. Each intake row 310 is used to communicate with the inlet 31 of the cooling distribution unit 3 and the input tube 120 of the liquid cooling row 1. In this way, overall communication for the refrigerant may be achieved.

Therefore, with the above-mentioned structure, the present disclosure may provide the precooling device integrated with the cooling distribution unit and the server liquid cooling system with the precooling device integrated with the cooling distribution unit.

The above only describes preferable embodiments of the present disclosure but is not intended to limit the protection scope of the present disclosure. Therefore, all equivalent structural changes based on the specification and the drawings of the present disclosure should be deemed to fall within the protection scope of the present disclosure.

What is claimed is:

1. A server liquid cooling system, comprising:
a pre-cooling device comprising:
a liquid cooling row comprising a condensation area, a flow distribution side in communication with one side of the condensation area, and a flow joining side in communication with another side of the condensation area;
a flow joining passage that is in communication with the flow distribution side of the liquid cooling row to receive a refrigerant from a server chassis; and
a flow distribution passage; and
a cooling distribution unit comprising an inlet and an outlet,
wherein the outlet is in communication with the flow distribution passage to deliver the refrigerant to the server chassis to perform a heat exchange with electronic components disposed in the server chassis, the refrigerant is received in the pre-cooling device by way of the flow joining passage to pre-cool the refrigerant in the pre-cooling device, and the inlet is in communication with the flow joining side to receive the refrigerant in the cooling distribution unit.

2. The server liquid cooling system of claim 1, further comprising:
a return tube, wherein the liquid cooling row is in communication with the flow joining passage through the return tube.

3. The server liquid cooling system of claim 2, further comprising
a conveying tube, wherein the flow distribution passage is in communication with the inlet through the conveying tube.

4. The server liquid cooling system of claim 1, wherein the pre-cooling device is mounted in a server cabinet between the server chassis and another server chassis.

5. The server liquid cooling system of claim 4, wherein the cooling distribution unit is mounted in the server cabinet below the server chassis.

6. A server liquid cooling system, comprising:
a first pre-cooling device comprising a liquid cooling row that is connected to a first server chassis, wherein the first pre-cooling devices receives a refrigerant from the first server chassis and pre-cools the refrigerant;
a second pre-cooling device comprising a liquid cooling row that is connected to a second server chassis, wherein the second pre-cooling device receives the refrigerant from the second server chassis and pre-cools the refrigerant; and
a cooling distribution unit comprising an inlet and an outlet, wherein the inlet is connected to the first and second pre-cooling devices to receive the refrigerant from the first and second pre-cooling devices, and the outlet is connected to the first and second server chassis to deliver the refrigerant to the first and second server chassis.

7. The server liquid cooling system of claim 6, wherein the first server chassis, the second server chassis, and the cooling distribution unit are mounted in a server cabinet.

8. The server liquid cooling system of claim 7, wherein the first pre-cooling device is disposed in the server cabinet between the first server chassis and the second server chassis.

9. The server liquid cooling system of claim 7, wherein the cooling distribution unit is mounted below the first server chassis in the server cabinet.

10. The server liquid cooling system of claim 7, further comprising:
an intake pipe that is disposed in the server cabinet, wherein the inlet of the cooling distribution unit is connected to the first and second pre-cooling devices through the intake pipe; and
an outgoing pipe that is disposed in the server cabinet, wherein the outlet of the cooling distribution unit is connected to the first and second server chassis through the outgoing pipe.

11. The server liquid cooling system of claim 10, wherein the intake pipe and the outgoing pipe are arranged vertically in the server cabinet.

12. A method of cooling server chassis, the method comprising:
receiving a refrigerant in a first server chassis to perform heat exchange between the refrigerant and electronic components disposed in the first server chassis;
in a first liquid cooling row, receiving the refrigerant from the first server chassis;
pre-cooling the refrigerant in the first liquid cooling row before flowing the refrigerant from the first liquid cooling row to a cooling distribution unit;
in the cooling distribution unit, receiving the refrigerant from the first liquid cooling row; and
supplying the refrigerant from the cooling distribution unit to the first server chassis.

13. The method of claim 12, further comprising:
receiving the refrigerant in a second server chassis to perform heat exchange between the refrigerant and electronic components disposed in the second server chassis;
in a second liquid cooling row, receiving the refrigerant from the second server chassis;
pre-cooling the refrigerant in the second liquid cooling row before flowing the refrigerant from the second liquid cooling row to the cooling distribution unit;
in the cooling distribution unit, receiving the refrigerant from the second liquid cooling row; and
supplying the refrigerant from the cooling distribution unit to the second server chassis.

14. The method of claim 13, wherein the refrigerant is supplied by the cooling distribution unit to the first and second server chassis along an outgoing pipe.

15. The method of claim 14, wherein the first and second server chassis are mounted in a server cabinet, and the outgoing pipe is arranged vertically in the server cabinet.
